(19) United States
(12) Patent Application Publication
(10) Pub. No.: US 2008/0310138 A1
(43) Pub. Date: Dec. 18, 2008

(54) Electronic Enclosure Having Elastomeric Circuit Board Standoffs

(75) Inventor: Gregory E. Arends, Cedar Park, TX (US)

Correspondence Address: Houston IP Department;JACKSON WALKER L.L.P., 1401 McKinney St., Suite 1900, Houston, TX, 77010, US

(73) Assignee: XPLORE TECHNOLOGIES CORPORATION OF AMERICA

(21) Appl. No.: 12/134,627

(22) Filed: Jun. 6, 2008

Related U.S. Application Data
(60) Provisional application No. 60/933,549, filed on Jun. 7, 2007.
(60) Provisional application No. 60/933,629, filed on Jun. 7, 2007.
(60) Provisional application No. 60/933,935, filed on Jun. 8, 2007.

(51) Int. Cl. H05K 7/12

(52) U.S. Cl. 361/808

(57) ABSTRACT

Electronic enclosures, enclosed circuit board assemblies, and computers having elastomeric truncated standoffs are provided. More particularly, systems and devices may comprise a computer case in which a plurality of elastomeric standoffs are mounted so as to support one or more circuit boards. The case may be formed of a first enclosure and a second enclosure with the standoffs secured therebetween. The elastomeric truncated standoffs pass partially through apertures in the circuit board such that the circuit board is supported by the standoffs and so that the circuit board is mechanically isolated from the case. Advantages include efficiently providing mechanical isolation to the circuit board and the components mounted to it, providing design flexibility by reducing or eliminating the necessity of permanently tooled or fixed boss mounts, and allowing elastomeric standoffs to be constructed of different materials than their corresponding enclosure.

### CROSS-REFERENCE TO RELATED APPLICATION

The present application claims priority to and the benefit of U.S. provisional patent application Ser. No. 60/933,549, filed on Jun. 7, 2007, U.S. provisional patent application Ser. No. 60/933,629, filed on Jun. 7, 2007, U.S. provisional patent application Ser. No. 60/933,935, filed on Jun. 8, 2007, which are hereby incorporated by reference.

### BACKGROUND

The present invention generally relates to enclosed circuit board assemblies, and more particularly to a circuit board support for use in a ruggedized notebook, tablet, convertible or other portable computer.

Conventional methods of enclosing circuit boards in an electronic enclosure typically include attaching circuit boards and their associated components directly to relatively rigid features of the electronic enclosure, such as bosses protruding from plastic moldings or metal standoffs attached to plastic or metal enclosures. Screws are usually used to secure the circuit board to the bosses. Typically, permanently tooled and rigid bosses are integrally molded into an enclosure.

Thus, conventional methods of supporting electronic boards within an enclosure provide little mechanical isolation to the boards. As such, shocks to the external enclosure or case are readily transmitted to the more delicate electronics mounted therein. Additionally, conventional methods for mounting circuit boards require screws to be installed during assembly, the installation and tightening of which can be cumbersome and inefficient. In particular, screws can be easily lost and are often difficult to manipulate, especially if small. Moreover, screws and their corresponding bosses can become stripped, rendering the entire sub assembly unusable. Another disadvantage of using screws is that over-tightening of screws can cause damage to the components being screwed together. In the case of delicate and expensive circuit boards, it is especially desirable to avoid such damage. In addition, permanent, tooled board supports or bosses are undesirable in that they reduce a manufacturer's flexibility in changing the design of the electronic enclosure and altering the location of components on the printed circuit boards. Finally, rigidly mounted supports or bosses do not allow for misalignment of mounting holes in the PCB's or associated components due to tolerance issues during manufacturing. The misalignment of the screw boss and the hole in the printed circuit board can often make it difficult or impossible to assemble the electronic enclosure.

### SUMMARY

The present invention generally relates to enclosed circuit board assemblies, and more particularly, to a circuit board support for use in a ruggedized notebook, tablet, convertible or other portable computer.

The support of the invention is an elastomeric truncated pylon or standoff which is mounted in a computer case to physically isolate electronic circuit boards disposed therein from the computer case or other components of the computer. The elongated standoff has a first end and a second end and a circuit board support structure defined therebetween. The circuit board has an aperture sized to allow at least a portion of the elongated elastomeric standoff to pass through the aperture until the circuit board abuts the support structure. In this way, the circuit board is supported by the standoff.

In one embodiment, the standoff is conical in shape and inserted into the aperture of the circuit board until the circuit board engages a portion of the standoff. Since the standoff is formed of an elastomeric material, the standoff can be compressed into the aperture such that the standoff engages both sides of the circuit board around the aperture.

In another embodiment, a slot may be formed around the circumference of the standoff. The standoff is inserted into the aperture until the board seats in the slot, thereby securing the board on the standoff.

In yet another embodiment of the invention, a first end of the standoff may be inserted into the aperture until the board abuts the support structure of the standoff. A sleeve may then be disposed over the first end and abut the circuit board so as to urge the circuit board against the support structure of the standoff. The sleeve may be integrally formed with the computer case or may be a separate component of the standoff itself.

The standoff may be attached between adjacent, mating sections of the computer case or may be carried on a component internal to the computer case. In this regard, the standoff may be attached with adhesives to avoid the need for additional fasteners, or the standoff may include a mounting structure at one or both ends, such as for example, a head, that engages an aperture in the case or internal components.

In one preferred embodiment, multiple standoffs are mounted between the mating sections of a computer case and one or more circuit boards are mounted on the standoffs in a plane or planes substantially parallel to the computer case sections. In the instance of multiple circuit boards carried by a single standoff, the standoff may have multiple support structures.

Advantages include efficiently providing mechanical isolation to the circuit board and the components mounted to it, providing design flexibility by reducing or eliminating the necessity of permanently tooled or fixed boss mounts, and allowing elastomeric standoffs to be constructed of different materials than their corresponding enclosure.

Other features and advantages of the present invention will be apparent to those skilled in the art. While numerous changes may be made by those skilled in the art, such changes are within the spirit of the invention.

### BRIEF DESCRIPTION OF THE DRAWINGS

A more complete understanding of the present disclosure and advantages thereof may be acquired by referring to the following description taken in conjunction with the accompanying figures, wherein:

FIG. 1A illustrate a cross-sectional view of one embodiment of the elastomeric electronic circuit board standoffs of the invention where the standoff includes a flange.

FIG. 1B illustrate a perspective view of one embodiment of the elastomeric electronic circuit board standoffs of the invention where the standoff is cylindrical in shape and includes a shoulder and sleeve.

FIGS. 1C-1E illustrate perspective views of examples of elastomeric electronic circuit board standoffs in accordance with various embodiments of the present invention.

FIG. 1F illustrate a perspective view of one embodiment of the elastomeric electronic circuit board standoffs of the invention where the standoff is conical in shape and includes a shoulder and sleeve.

FIG. 1G illustrate a cross-sectional view of the standoff of FIG. 1F.

FIG. 1H illustrate a perspective view of the standoff of FIG. 1F with a mounting head incorporated thereon.

FIG. 1I illustrate a cross-sectional view of the standoff of FIG. 1H.

FIG. 1J illustrates a cross-sectional view of a partially conical shaped standoff.

FIGS. 2A-2D illustrate cross-sectional and perspective views of examples of an electronic enclosure having elastomeric electronic circuit board supports or standoffs in accordance with various embodiments of the present invention.

FIG. 3 illustrates a cross-sectional view of a portion of an electronic enclosure using an elastomeric electronic circuit board support or standoff having a notch feature in accordance with one embodiment of the present invention.

FIGS. 4A-4B illustrate cross-sectional and perspective views of an electronic enclosure using elastomeric electronic circuit board supports or standoffs having sleeve and notch features in accordance with various embodiments of the present invention.

FIG. 5 illustrates a cross-sectional view of a standoff of the invention with multiple board support structures secured between electronic enclosures.

While the present invention is susceptible to various modifications and alternative forms, specific exemplary embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DESCRIPTION OF PREFERRED EMBODIMENTS

The present invention generally relates to enclosed circuit board assemblies having elastomeric standoffs for supporting an electronic circuit board. Methods of use are also provided.

Certain embodiments of the present invention use an elastomeric standoff for supporting a circuit board in an electronic enclosure, particularly electric enclosures for notebook, convertible, tablet or similar portable computer, which are more frequently subject to shocks from handling, dropping and the like. The circuit boards have apertures to allow the elastomeric standoff to partially penetrate therethrough. All or a portion of the elastomeric standoff may be conical in shape, allowing the circuit board to be supported on the elastomeric standoff. Other embodiments of an elastomeric standoff include a shoulder or groove, which provides a surface upon which the circuit board may be supported. Other retention and board support features may be optionally incorporated into various embodiments of the present invention so as to restrict the lateral and axial movement of the circuit board as mounted on the standoff.

Advantages of the present invention include the efficient mechanical isolation of the circuit board and the components mounted to it, design flexibility since circuit board mounting points are no longer required to be permanently tooled or have fixed boss mounts and the ability of the system to be more forgiving of manufacturing tolerances and concentricity of the holes in the printed circuit board.

To facilitate a better understanding of the present invention, the following examples of certain embodiments are given. In no way should the following examples be read to limit, or define, the scope of the invention.

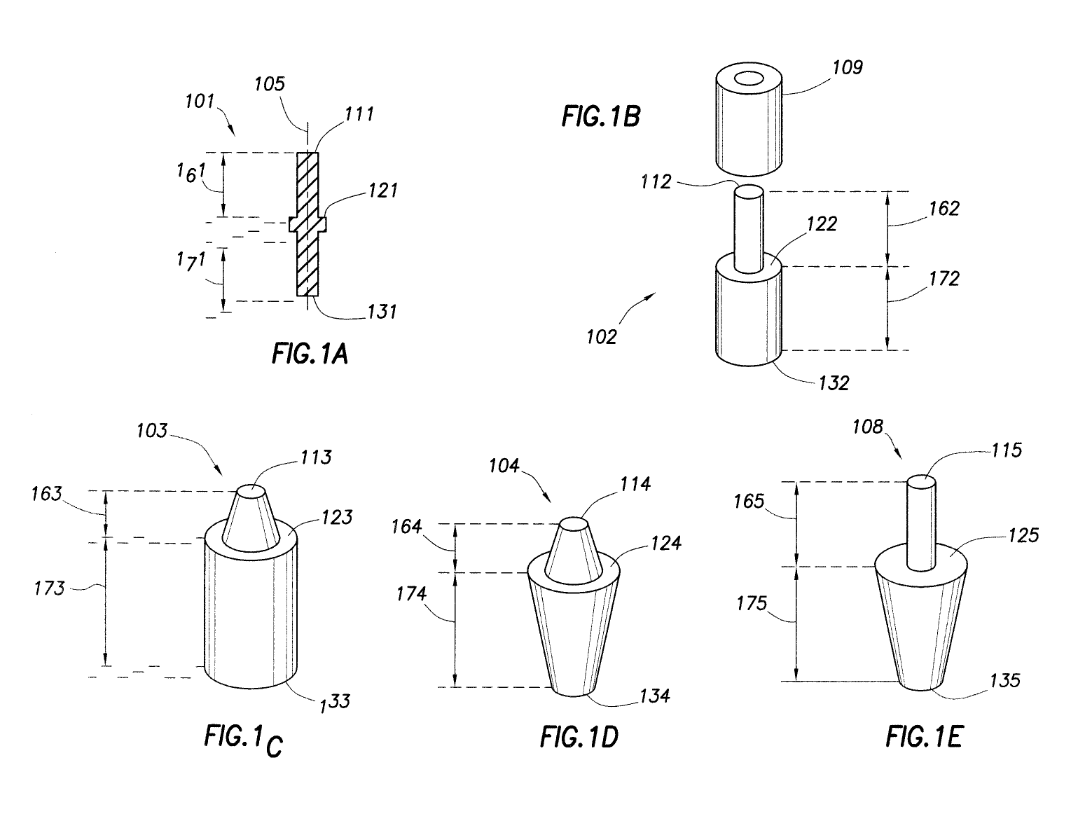

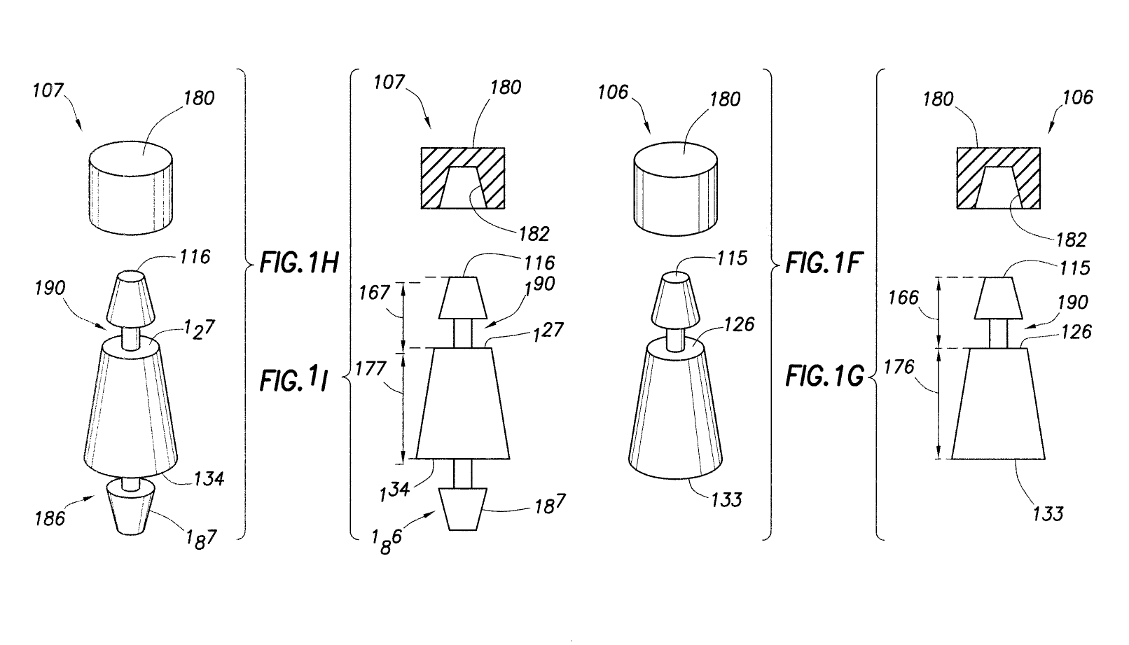

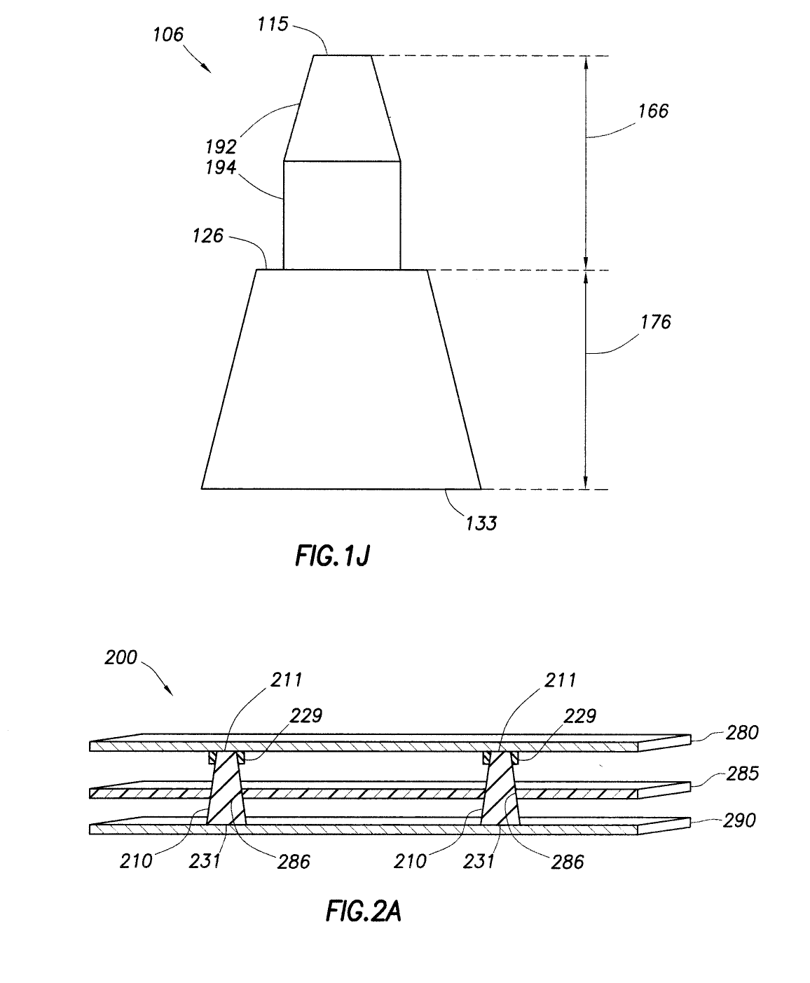

FIGS. 1A-1E illustrate perspective views of examples of elastomeric electronic circuit board supports or standoffs in accordance with several embodiments of the present invention.

As can be seen in the various views of FIGS. 1A-1E, elastomeric standoffs of the present invention may be configured in a variety of forms. FIG. 1A shows a cross-sectional view of an elastomeric standoff. Elastomeric standoff 101 is of an elongated shape and has first end 111, a second end 131 and is generally disposed along a central axis 105 A board support structure in the form of a flange 121 is defined on standoff 101 along axis 105 between the first and second ends 111, 131.

In FIG. 1A, first and second portions 161 and 171 are substantially cylindrical. As will be apparent in other figures discussed below, generally, first end 111 and second end 131 attach to an enclosure (not shown) or sections of an enclosure or other internal structure of a computer, whereas shoulder 121 provides a surface or point along the length of the standoff for support of a circuit board (not shown).

FIG. 1B illustrates a perspective view of an alternative embodiment of an elastomeric standoff. Elastomeric standoff 102 has first end 112, shoulder 122, and second end 132. As before, first and second portions 162 and 172 are substantially cylindrical. In this embodiment, second portion 172 is provided with a larger diameter than first portion 162, thereby forming a board support structure in the form of a shoulder 122 where first and second portions 162, 172 meet. A sleeve 109 is adapted to interface with first portion 162 of elastomeric standoff 102 by mounting on first end 112. In this regard, sleeve 109 is provided with an aperture 2 therethrough. Aperture 2 is sized to fit over first end 112. Once a circuit board (not shown) is positioned on shoulder 122, sleeve 109 is disposed on standoff 102 to secure the circuit board in place. In this regard, although not necessary, it is preferable that sleeve 109 is formed of the same elastomeric material as standoff 102 and that aperture 2 be sized to have a slight interference fit with first end 112, thereby maintaining a friction fit thereon.

FIG. 1C illustrates a perspective view of another alternative embodiment of an elastomeric standoff. Elastomeric standoff 103 has first end 113, a second end 133 and a board support structure in the form of a shoulder 123 formed at the junction of said first end 113 and second end 133. First portion 163 is substantially conical and truncated, whereas second portion 173 is forms a support column of substantially cylindrical shape. Of course, those skilled in the art will appreciate that the support column shown in FIG. 1C, as well as any structure providing similar support for the various embodiments described herein, can have any shape, since it simply forms a support shoulder 123 and supports first portion 163 on which a board may be mounted.

FIG. 1D illustrates a perspective view of another alternative embodiment of an elastomeric standoff. Elastomeric standoff 104 has first end 114, shoulder 124, and second end 134. First portion 164 is substantially conical and truncated, and second portion 174 is substantially conical and truncated, yet inverted relative to said first portion 164, thereby forming shoulder 124 at the intersection of the first and second portions 164, 174.

FIG. 1E illustrates a perspective view of yet another alternative embodiment of an elastomeric standoff. Elastomeric standoff 105 has first end 115, shoulder 125, and second end 135. First portion 165 is substantially cylindrical, whereas second portion 175 is substantially conical, yet inverted and truncated.

FIGS. 1F and 1G illustrates another embodiment of a conical elastomeric standoff with a corresponding sleeve. Elastomeric standoff 106 has first end 115, a board support structure in the form of a shoulder 126, and second end 133. In the case of standoff 106, first and second portions 166 and 176 are substantially conical in shape with a gradually increasing outer diameter from first end 115 to second end 133. In this embodiment, shoulder 126 is formed by providing a radial notch 190 in standoff 106. A sleeve 180 is adapted to interface with first portion 166 of elastomeric standoff 106 by mounting on first end 115. In this regard, sleeve 180 is provided with an aperture 182 sized to engage first end 115. Once a circuit board (not shown) is positioned on shoulder 126, sleeve 180 is disposed on standoff 106 to secure the circuit board in place against shoulder 126. In this regard, although not necessary, it is preferable that sleeve 180 is formed of the same elastomeric material as standoff 106 and that aperture 182 be sized, although not necessary, to have a slight interference fit with first end 115, thereby maintaining a friction fit thereon. In another embodiment, sleeve 180 may be an integrally formed structure on the computer case, and in such case, would more likely be formed of the same material as the computer case.

FIGS. 1H and 1I illustrate another embodiment of a conical elastomeric standoff with an integrally formed attachment structure. Elastomeric standoff 107 has first end 116, a shoulder 127, and second end 134. In the case of standoff 107, first and second portions 167 and 177 are substantially conical in shape with a gradually increasing outer diameter from first end 116 to second end 134. In this embodiment, shoulder 127 is formed by providing a radial notch 190 in standoff 107. A sleeve 180 is adapted to interface with first portion 167 of elastomeric standoff 107 by mounting on first end 116. In this regard, sleeve 180 is provided with an aperture 182 sized to engage first end 116. Once a circuit board (not shown) is positioned on shoulder 127, sleeve 180 is disposed on standoff 107 to secure the circuit board in place against shoulder 127.

In this preferred embodiment, standoff 107 is provided with an attachment structure 186. Preferably, attachment structure 186 is integrally formed as part of standoff 107, but need not be. In this embodiment, attachment structure 186 is a shown as a head 187 that can engage an aperture provided in the surface to which standoff 107 is to be mounted. Head 187 forms a lower shoulder and cone that can be pulled through an aperture provided in an enclosure as a secure attachment point. For example, the lower computer case (not shown) may be formed with an aperture disposed for receipt of head 186. Those skilled in the art will appreciate that attachment structure 186 may be desirable in instances where additional mechanical strength is required of standoff 107.

In the preferred embodiment of the invention shown in FIG. 1J, a standoff similar to standoff 106 of FIG. 1G is shown. However, in standoff 106 of FIG. 1J, only the upper part 192 of first portion 166 is conical in shape. The lower part 194 of first portion 166 is cylindrical in shape and extends to abut second portion 176, thereby forming shoulder 126. Preferably, the diameter of the cylinder shape is sized to be approximately the same size as the mounting aperture of the printed circuit board. Those skilled in the art will appreciate that such a configuration permits the smaller diameter conical part 192 of first portion 166 to be more easily guided into the mounting aperture on the circuit board, further facilitating assembly.

The standoffs of the invention may be attached between adjacent, mating sections of the computer case or may be carried on a component internal to the computer case. Likewise, a standoff may be secured or otherwise attached at both ends of the standoff or it may be secured or otherwise attached at only one end of the standoff. In this regard, the standoff is preferably attached with adhesives to avoid the need for additional fasteners. The use of adhesive to attach the elastomeric standoffs allows for the realignment or relocation of the standoffs at any time thereby allowing extensive printed circuit board changes to be made without any effect on the enclosure molding tools. Furthermore, attaching the standoffs utilizing adhesives and a robotic placement system allows the locations of the standoffs to be adjusted to fit enclosure tooling errors after the fact.

In some situations (typically ones in which the product experiences high levels of vibration or shock), more strength may be required of the elastomeric standoff and in this case, it is possible to utilize a variation of the elastomeric standoff (illustrated in FIGS. 1H and 1I) that has a mounting structure such as structure 186. This more secure mounting can be achieved utilizing a mounting structure incorporated on the standoff, a non-limiting example of which is illustrated in FIGS. 1H-1E.

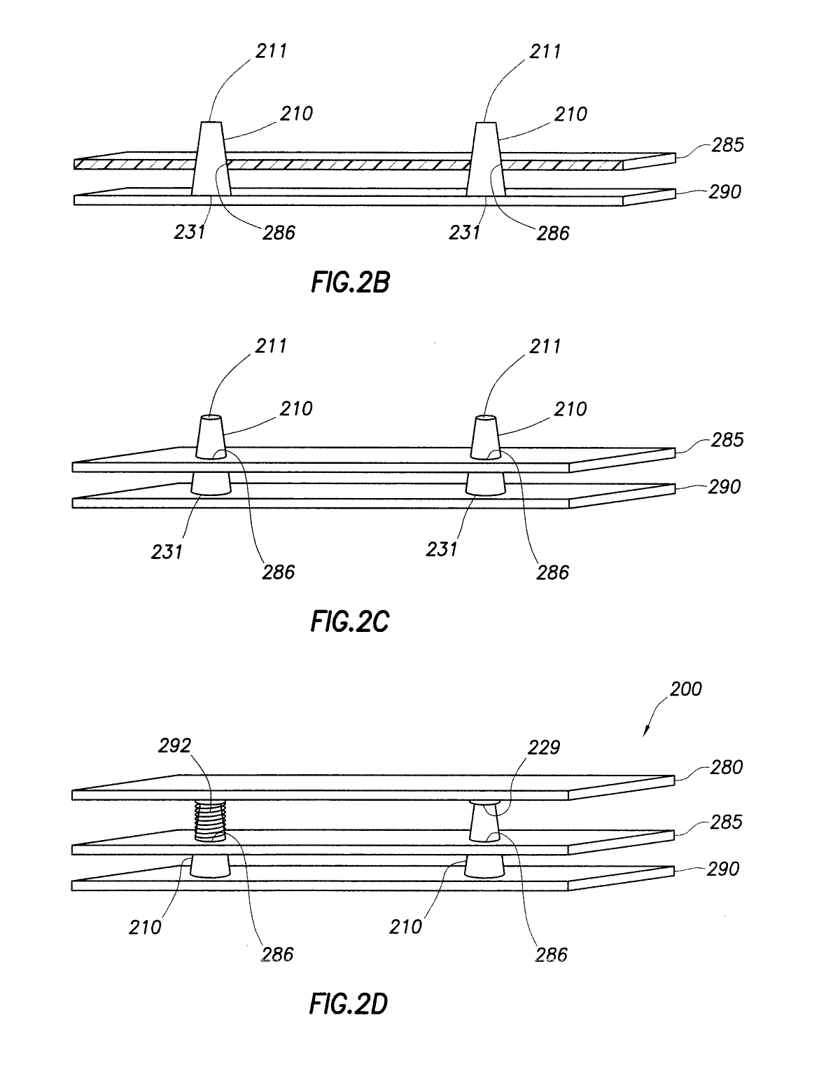

FIGS. 2A-2D illustrate cross-sectional and perspective views of examples of an electronic enclosure having elastomeric electronic circuit board supports or standoffs in accordance with various embodiments of the present invention.

FIG. 2A is a cross-sectional view of an example of electronic enclosure 200 utilizing elastomeric standoffs 210. Elastomeric standoffs 210 are mounted between a first enclosure 280 and a second enclosure 290. While the term “enclosure” as used herein can include the outer shell, section or casing of a computer, it need not be limited to such, and is meant to include any structural component of a computer to which a standoff 210 could be attached. For example, enclosures 280, 290 could simply be a board—even another circuit board—mounted within a computer casing. With reference to FIG. 2A, more particularly, second ends 231 of elastomeric standoffs 210 are engaged by second enclosure 290, and first ends 211 of elastomeric standoffs 210 are engaged by first enclosure 280. Engagement of first and second ends 211 and 231 may be by any suitable method known in the art including, but not limited to, adhesion bonding, thermal bonding, pressure bonding, or any combination thereof, mounting structures or fasteners. In this same vein, standoff 210 may simply be secured by compression between enclosures 280 and 290, or may utilize one or more retention devices provided on an enclosure, such as enclosures 280, 290, to secure a standoff end, such as ends 211 and 231.

In the illustrated embodiment, circuit board 285 has apertures 286 through which a portion of substantially conical elastomeric standoffs 210 may pass. In this way, circuit board 285 rests on and is supported by elastomeric standoffs 210. That is, apertures 286 are sized to allow a partial penetration of elastomeric standoffs 210. Those skilled in the art will appreciate that since standoff 210 is elastomeric, circuit board 285 can be compressed onto standoff 210 so as to achieve an interference fit between aperture 286 and standoff 210, ensuring that board 285 remains tightly secured on standoff 210.

Likewise, in the illustrated embodiment, optional retention device 229 is provided on first enclosure 280 so as to mate with, engage or otherwise interact with first ends 211 of elastomeric standoffs 210. In certain embodiments, retention device 229 allows first ends 211 of elastomeric standoffs 210 to be mechanically attached to first enclosure 280 without any adhesion or other bonding. In this embodiment, retention device 229 may be a metal stamping or plastic molding integrally formed as part of the enclosure.

While elastomeric standoffs 210 are depicted here as substantially conical, it is explicitly recognized that elastomeric standoffs 210 could be formed in any shape suitable for supporting circuit board 285, including, but not limited to, the exemplary shapes depicted in FIGS. 1A-1I.

FIG. 2B illustrates a cross-sectional view of electronic enclosure 200 as it exists earlier in the assembly process before the addition of first enclosure 280. Here, circuit board 285 is mounted on elastomeric standoffs 210 after elastomeric standoffs 210 is secured to second enclosure 290. The portion of elastomeric standoff 210 that contacts or engages circuit board 285 forms the board support structure of standoff 210. In this case, the board support structure is simply a portion of the conical surface of standoff 210. Similarly, FIG. 2C illustrates a perspective view of the same. FIG. 2D illustrates a perspective view of electronic enclosure 200 after attachment of first enclosure 280 to elastomeric standoffs 210.

A biasing device 292 may also be provided to further urge board 290 against the board support structure.

FIG. 3 illustrates a cross-sectional view of a portion of an electronic enclosure using an elastomeric electronic circuit board support or standoff having a notch feature in accordance with one embodiment of the present invention.

In this embodiment, elastomeric standoff 310 is attached to second enclosure 390 at second end 331. Circuit board 385 is supported by elastomeric standoff 310. More particularly, elastomeric standoff 310 partially penetrates apertures 386 of circuit board 385. A board support structure in the form of a radial notch 328, also referred to herein as a barb feature, is defined on standoff 310 at some point along its length. Circuit board 385 seats in notch 328 as shown. Preferably, the width of notch 328 is approximately the same as the thickness of circuit board 385 so as to securely engage board 385 when seated in notch 328. Those skilled in the art will appreciate that notch 328 may be used to provide a more stable and/or more secure mating of circuit board 385 with elastomeric standoff 310. In this embodiment, a second enclosure need not be used to secure standoff 310.

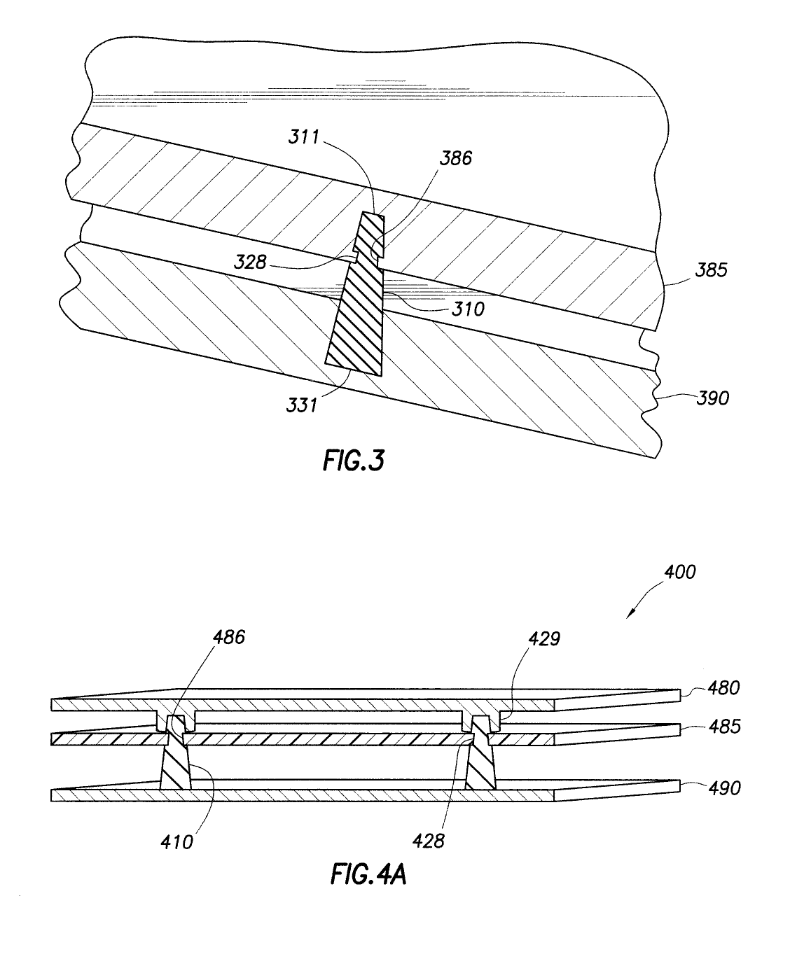

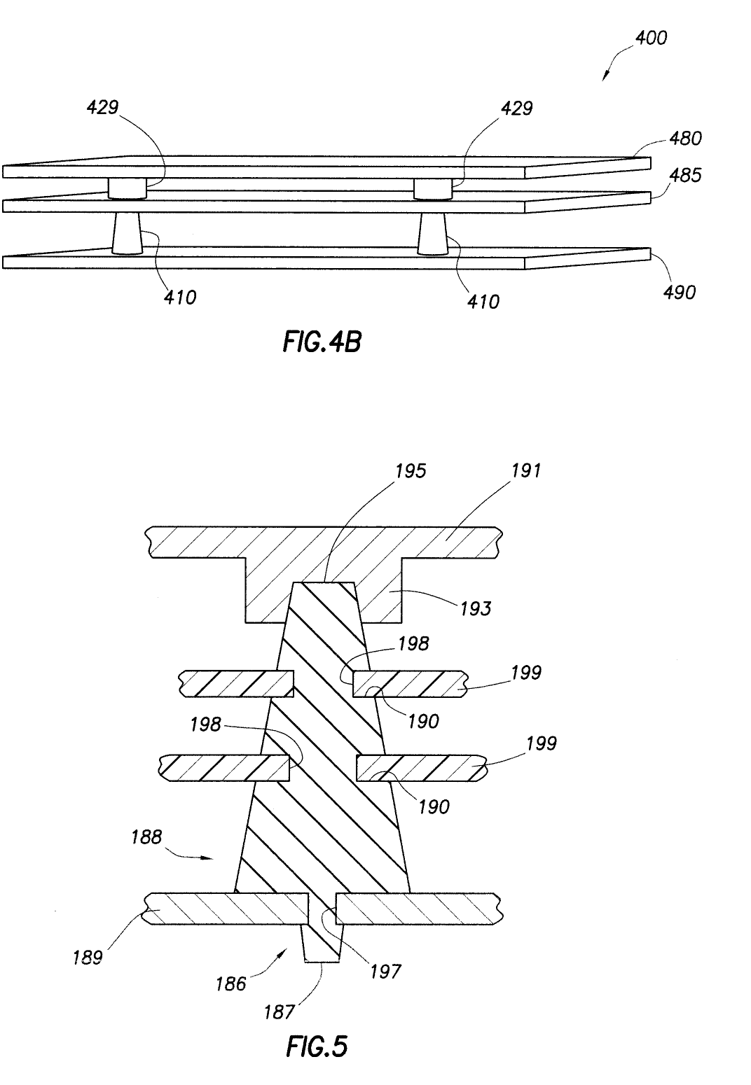

FIGS. 4A-4B illustrate cross-sectional and perspective views, respectively, of another embodiment of the invention. In these illustrations, there is shown a cross-sectional view of electronic enclosure 400 comprising first enclosure 480, circuit board 485 with apertures 486, second enclosure 490, and elastomeric standoffs 410. In this embodiment, notches 428 interact or otherwise mate with apertures 486. Retention devices 429, also referred to herein as sleeves, interact or otherwise mate with elastomeric standoffs 410. Retention device 429 fits over the end of standoff 410 much in the same was as retention device 229 shown in FIG. 2A. In this way, the notch feature and the sleeve feature serve to stabilize and mechanically isolate circuit board 485.

More specifically, retention device 429 is disposed to seat against circuit board 485, thereby applying pressure to urge board 485 into continued engagement with standoff 410. Those skilled in the art will appreciate that while notch 428 is also depicted in this embodiment, it need not be. The compressive force of retention device 429 against circuit board 485, thereby urging circuit board against standoff 410 is sufficient to accomplish the goal of the invention even without notch 428. In this embodiment, while the inner diameter of retention device 429 is shown to be sized so as to engage the end of standoff 410, it need not be so long as retention device provides seating pressure on board 410 as described herein.

As described above, retention device or sleeve 429 may be integrally formed as part of the computer enclosure or it may be a separate component of standoff 410. Likewise, it may be used to simply engage the end standoff 410 or may be utilized to apply a stabilizing force against a circuit board.

In another embodiment, to further isolate board 485 on standoff 410, a spring or similar biasing device (such as is shown as 292 in FIG. 2D) may be disposed between retention device 429 and board 485 so that the spring provides the seating pressure on board 410. Of course, in such an embodiment, such a spring or biasing device may simply be engaged directly by enclosure 480 without the need for retention device 429. Preferably, such a spring or biasing device fits around the end of standoff 410 and is retained in place on standoff 410 by enclosure 480. One non-limiting example would be a coiled spring disposed on the end of standoff 410 and compressed between enclosure 480 and board 410.

It is explicitly recognized that the notch features and/or the retention features discussed herein may be combined with the other embodiments shown herein. Also, it is explicitly recognized that more than one circuit board may be supported by a portion or portions of the elastomeric standoffs disclosed herein. In such case, for example, apertures in the circuit boards may be sized differently so that each circuit board engages a different portion of said standoff. Likewise, said standoff may be provided with multiple support structures along its length, each support structure configured to engage a different circuit board. Spacers may be provided between adjacent circuit boards. Such spacers may be disposed around the standoff or may be otherwise simply disposed between the circuit boards. Preferably, such spacers are elastomeric so as to further provide isolation between adjacent circuit boards, but may be formed of any material.

FIG. 5 illustrates a non-limiting example of a standoff with many of the combined features disclosed herein. Specifically shown in FIG. 5 is a conically shaped standoff 188 secured between a first enclosure 189 and a second enclosure 191. Second enclosure 191 is provided with a sleeve or retention device 193 disposed to engage one end 195 of standoff 188. Disposed at the other end 196 of standoff 188 is an attachment structure 186 in the form of a head 187 seated in an aperture 197 of first enclosure 189. Defined along the axial length of standoff 188 are multiple board support structures. In this case, board support structures are radial notches 190, each of which is disposed to engage an aperture 189 in circuit board 199. Preferably notches 190 secure circuit boards 199 so that the boards are substantially parallel to one another. It will be appreciated that the apertures 189 of boards 199 may be of different sizes so that certain boards can only seat in certain notches. For example, the upper board in FIG. 5 may have a smaller diameter aperture 189 than the lower board so that the upper board could not be inadvertently secured on standoff 188 in the wrong position.

Any of the features and components disclosed in Applicant's concurrently filed non-provisional patent applications may be used in conjunction with embodiments of the present invention, namely U.S. patent application Ser. No. ______, entitled “Electronic Enclosure Fastening Belt” (which claims priority to U.S. Provisional Application Ser. No. 60/933,549) and U.S. Patent Application Serial No. ______, entitled “Configurable Computer System and Methods of Use” (which claims priority to U.S. provisional Application Ser. No. 60/933,629), the specifications of which are hereby incorporated by reference. In particular, it is explicitly recognized that embodiments described in these concurrently-filed specifications may be used in conjunction with the embodiments herein to eliminate traditional fasteners.

Therefore, the present invention is well adapted to attain the ends and advantages mentioned as well as those that are inherent therein. The particular embodiments disclosed above are illustrative only, as the present invention may be modified and practiced in different but equivalent manners apparent to those skilled in the art having the benefit of the teachings herein. Furthermore, no limitations are intended to the details of construction or design herein shown, other than as described in the claims below. It is therefore evident that the particular illustrative embodiments disclosed above may be altered or modified and all such variations are considered within the scope and spirit of the present invention. Also, the terms in the claims have their plain, ordinary meaning unless otherwise explicitly and clearly defined by the patentee.

What is claimed is:

1. An enclosed circuit board assembly comprising:
a first enclosure;
an elastomeric truncated standoff wherein the elastomeric truncated standoff is substantially conical and wherein the elastomeric truncated standoff has a first end and a second end, wherein the first end has a diameter greater than the second end;
wherein one end of the elastomeric truncated conical standoff is attached to the first enclosure;
a circuit board having an aperture sized to allow a partial penetration of the elastomeric truncated standoff through the aperture of the circuit board; and
wherein the circuit board is supported on the elastomeric truncated conical standoff by placement of the elastomeric truncated standoff through the aperture of the circuit board.

2. The enclosed circuit board assembly of claim 1 wherein the elastomeric truncated standoff further comprises a second enclosure, wherein one end of the elastomeric standoff is engaged by the first enclosure and the other end of the elastomeric standoff is engaged by the second enclosure.

3. The enclosed circuit board assembly of claim 1 wherein the elastomeric truncated standoff further comprises a groove around the circumference of the elastomeric truncated standoff wherein the groove is sized to mate with the aperture of the circuit board.

4. The enclosed circuit board assembly of claim 1 wherein the second enclosure further comprises a retention device for mating with the second end of the elastomeric truncated standoff.

5. The enclosed circuit board assembly of claim 1 wherein the first and second enclosures comprise the outer case of a portable computer.

6. An enclosed circuit board assembly comprising:
a first enclosure;
an elongated elastomeric standoff, wherein the elastomeric standoff has a first end and a second end and a support structure defined therebetween;
wherein the one end of the elastomeric standoff is attached to the first enclosure; and
a circuit board having an aperture sized to allow at least a portion of the elongated elastomeric standoff to pass through the aperture until the circuit board abuts the support structure such that the circuit board is supported on the support structure of the elastomeric standoff.

7. The enclosed circuit board assembly of claim 6, wherein the elastomeric truncated standoff further comprises a second enclosure, wherein one end of the elastomeric standoff is engaged by the first enclosure and the other end of the elastomeric standoff is engaged by the second enclosure.

8. The enclosed circuit board assembly of claim 6 wherein the elongated elastomeric standoff is substantially conical in shape.

9. The enclosed circuit board assembly of claim 8 wherein the support structure is a portion of the outer surface of the conical shape.

10. The enclosed circuit board assembly of claim 6 wherein the support structure is a protruding flange upon which the circuit board may be supported.

11. The enclosed circuit board assembly of claim 6 wherein the standoff tapers from the first end to the second end.

12. The enclosed circuit board assembly of claim 6 wherein the support structure is a shoulder.

13. The enclosed circuit board assembly of claim 6 wherein the standoff has a first portion of a first dimension extending from the first end and a second portion of a second dimension, different than the first dimension, extending from the second end and joined with the first portion at an interface, wherein a shoulder is formed at the interface.

14. The enclosed circuit board assembly of claim 6 wherein the standoff has a first portion extending from the first end and a second portion extending from the second end and joined with the first portion at an interface, wherein a shoulder is formed at the interface.

15. The enclosed circuit board assembly of claim 13 wherein the first portion is substantially conical and the second portion is substantially cylindrical and wherein the first portion increases in diameter gradually from the first end to the shoulder.

16. The enclosed circuit board assembly of claim 13 wherein the first portion is substantially conical and the second portion is substantially conical, wherein the first portion increases in diameter gradually from the first end to the shoulder, and wherein the second portion increases in diameter gradually from the second end to the shoulder

17. The enclosed circuit board assembly of claim 13 wherein the first portion is substantially cylindrical and the second portion is substantially conical and wherein the second portion increases in diameter gradually from the second end to the shoulder

18. The enclosed circuit board assembly of claim 13 wherein the standoff is substantially cylindrical in shape.

19. The enclosed circuit board assembly of claim 6 wherein the standoff is substantially cylindrical in shape and has a first portion of a first diameter extending from the first end and a second portion of a second larger diameter extending from the second end and joined with the first portion at an interface, wherein a shoulder is formed at the interface.

20. The enclosed circuit board assembly of claim 6 further comprising a sleeve disposed to fit over the end of said standoff.

21. The enclosed circuit board assembly of claim 20, wherein said sleeve abuts the circuit board.

22. The enclosed circuit board assembly of claim 20, wherein said sleeve extends from the enclosure.

23. The enclosed circuit board assembly of claim 6, further comprising a spring disposed around the end of said standoff between said circuit board and said enclosure so as to bias said circuit board against said standoff.

24. The enclosed circuit board assembly of claim 20 wherein the sleeve is a retention device that mates with the second end of the elastomeric truncated standoff.

25. A computer, the computer comprising:
a computer case,
a first enclosure,
a second enclosure;
a circuit board disposed within said case;
a microprocessor disposed on the circuit board;
memory media disposed on the circuit board;
an elongated elastomeric standoff, wherein the elastomeric standoff has a first end and a second end and a support structure defined therebetween;
wherein the one end of the elastomeric standoff is attached to the first enclosure;
wherein the circuit board has an aperture sized to allow at least a portion of the elongated elastomeric standoff to pass through said aperture until said circuit board abuts said support structure such that the circuit board is supported on the support structure of the elastomeric standoff.

26. The computer of claim 25 wherein the second enclosure interfaces with the second end of the elastomeric standoff.

27. The computer of claim 25 wherein the support structure is integral to the elastomeric truncated standoff.

28. The computer of claim 25 wherein the elastomeric standoff further comprises a notch for mating with the circuit board and wherein the one enclosure comprises a sleeve for engaging with an end of the elastomeric standoff.

29. The computer of claim 25 further comprising a plurality of elastomeric standoffs each elastomeric standoff having a first end and a second end, the first end of each elastomeric standoff being engaged by the first enclosure and the second end of each elastomeric standoff being engaged by the second enclosure.

30. The computer of claim 25 further comprising a plurality of circuit boards, wherein each circuit board has an aperture and said apertures of said circuit boards are of a different size such that each circuit board abuts a different portion of the elastomeric standoff so as to be substantially parallel to one another.

31. The computer of claim 30, further comprising a spacer disposed between the parallel circuit boards.

32. The computer of claim 31, wherein said spacer is disposed around said standoff.

33. The computer of claim 25, wherein said first and second enclosures form the computer case.

34. The computer of claim 25, wherein said standoff is conical in shape.

35. The computer of claim 25, wherein said standoff further comprises a head at one end and said first enclosure includes an aperture in which said standoff head is seated.

36. A method for assembling an electronic enclosure, said method comprising the steps of:
providing a first enclosure;
providing an elongated elastomeric standoff, wherein the elastomeric standoff has a first end and a second end and a support structure defined therebetween;
engaging the first end of the elongated elastomeric standoff with the first enclosure;
providing a circuit board having an aperture sized to allow at least a portion of the elongated elastomeric standoff to pass through the aperture;
mounting the circuit board on the standoff so as to allow the elongated elastomeric standoff to partially pass through the aperture until the circuit board abuts the support structure such that the circuit board is supported on the support structure of the elastomeric standoff;
providing a second enclosure; and
engaging the second end of the elastomeric standoff with the second enclosure.

37. A method for assembling a computer, said method comprising the steps of:
providing a case for a computer;
providing an elastomeric truncated standoff, wherein the elastomeric truncated standoff is substantially conical and wherein the elastomeric truncated standoff has a first end and a second end, wherein the first end has a diameter greater than the second end;
securing the elastomeric truncated conical standoff within said case;
providing a circuit board having an aperture sized to allow a partial penetration of the elastomeric truncated standoff through the aperture of the circuit board; and
mounting the circuit board on the standoff by placement of the elastomeric truncated standoff through the aperture of the circuit board.
